(19) United States
(12) Patent Application Publication
(10) Pub. No.: US 2008/0087881 A1
(43) Pub. Date: Apr. 17, 2008

(54) Semiconductor Multilayer Substrate, Method For Producing Same And Light-Emitting Device

(76) Inventors: Kazumasa Ueda, Ibaraki (JP); Naohiro Nishikawa, Ibaraki (JP)

Correspondence Address: FITCH, EVEN, TABIN & FLANNERY, P. O. BOX 18415, WASHINGTON, DC, 20036, US

(21) Appl. No.: 11/667,978

(22) PCT Filed: Nov. 22, 2005
(86) PCT No.: PCT/JP05/21936

§ 371 Date: May 17, 2007

(30) Foreign Application Priority Data
Nov. 24, 2004 (JP) 2004-338627

(51) Int. Cl. H01L 51/50; H01L 51/56

(52) U.S. Cl. 257/40; 438/99; 257/E51.018

(57) ABSTRACT

The present invention provides a semiconductor multilayer substrate used as a high-brightness semiconductor light-emitting device, a method for producing the same, and a light-emitting device. The semiconductor multilayer substrate comprises a semiconductor layer containing an inorganic particle made of substance other than metal nitrides. The method for producing a semiconductor multilayer substrate comprises the steps (a) and (b) of: (a) placing an inorganic particle made of substance other than metal nitrides on a substrate and (b) growing a semiconductor layer.

### TECHNICAL FIELD

The present invention relates to a semiconductor multilayer substrate used as a high-brightness semiconductor light-emitting device, a method for producing the same, and a light-emitting device.

### BACKGROUND ART

Semiconductor multilayer substrates are used as semiconductor light-emitting devices, such as nitride semiconductor light-emitting devices, polymer LEDs, and low-molecular weight organic LEDs, which are parts of various displays.

For example, nitride semiconductor multilayer substrates including nitride semiconductor layers expressed by the formula InₓGa_{y}AlₐN (0≦x≦1, 0≦y≦1, 0≦z≦1, and x+y+z=1) are used as semiconductor light-emitting devices such as ultraviolet, blue, and green light-emitting diodes or ultraviolet, blue, and green laser diodes; and these semiconductor light-emitting devices are required to have high brightness in terms of improvement in performance of displays.

### DISCLOSURE OF THE INVENTION

An object of the present invention is to provide a semiconductor multilayer substrate used as a high-brightness light-emitting device.

The present inventors conducted extensive studies on semiconductor multilayer substrates; as a result, have completed the invention.

That is, the invention provides a semiconductor multilayer substrate comprising a semiconductor layer containing an inorganic particle made of substance other than metal nitrides.

Further, the invention provides a method for producing a semiconductor multilayer substrate comprising the steps (a) and (b) of:

(a) placing an inorganic particle made of substance other than metal nitrides on a substrate and

(b) growing a semiconductor layer.

Furthermore, the invention provides a light-emitting device comprising the semiconductor multilayer substrate described above.

### BRIEF DESCRIPTION OF THE DRAWINGS

FIG. 1 shows a method for producing a nitride semiconductor multilayer substrate.

FIG. 2 shows a semiconductor multilayer substrate including a low-temperature buffer layer and a facet forming layer.

FIG. 3 shows an electron microscope photograph of the cross section of the semiconductor multilayer substrate.

FIG. 4 shows the relationship between Al content in the low-temperature buffer layer and the full width at half maximum of the diffraction peak of its (302) plane calculated from by X-ray diffraction rocking curve.

### DESCRIPTION OF THE REFERENCE NUMERALS

11 substrate
12 inorganic particle
13 growth region in which nitride semiconductor is to be grown
14 facet structure of nitride semiconductor
15 epitaxially grown nitride semiconductor layer
21 substrate
22 low-temperature buffer layer
23 inorganic particle
24 facet structure
25 semiconductor layer

### Mode for Carrying Out the Invention

[Semiconductor Multilayer Substrate]

A semiconductor multilayer substrate according to the present invention includes a semiconductor layer and usually includes a substrate and a semiconductor layer.

[Semiconductor Layer]

The semiconductor layer is made of, for example, metal nitride, high-molecular weight organic compound, or low-molecular weight organic compound. When the semiconductor layer is made of metal nitride, the semiconductor multilayer substrate is used as a nitride semiconductor light-emitting device. And further, when the semiconductor layer is made of high-molecular weight organic compound, the semiconductor multilayer substrate is used as a high-molecular weight organic LED and when the semiconductor layer is made of low-molecular weight organic compound, the semiconductor multilayer substrate is used as a low-molecular weight organic LED. The composition of the semiconductor layer may be measured by cutting a semiconductor multilayer device and then analyzing the cross section of the device using SEM-EDX.

Preferably, the semiconductor layer is made of metal nitride such as InₓGa_{y}Al_{z}N (where 0≦x≦1, 0≦y≦1, 0≦z≦1, and x+y+z=1). The semiconductor layer may include layers required for the operation of the nitride semiconductor light-emitting device such as n-type conductive layers (such as n-type contact layer and n-type clad layer), light-emitting layer, and p-type conductive layers (such as p-type contact layer and p-type clad layer).

Furthermore, the semiconductor layer may include, for example, single layer, multilayer such as thick-film layer and a superlattice thin-film layer, or buffer layer in viewpoint of improving crystallity of the layers required for the operation of the nitride semiconductor light-emitting device.

The semiconductor layer contains an inorganic particle made of substance other than metal nitrides. The semiconductor layer may exist between the light-emitting layer and the substrate, or may exist on the opposite side of the light-emitting layer with respect to the substrate. It is preferable that the semiconductor layer exists between the light-emitting layer and the substrate. It is more preferable that the semiconductor layer exists between the light-emitting layer and the substrate, and that the semiconductor layer is contacted with the substrate.

Moreover, in the semiconductor layer, the full width at half maximum (FWHM) of the diffraction peak of (302) plane calculated from an X-ray diffraction rocking curve is preferably not more than 650 arcsec.

[Inorganic Particle]

A inorganic particle is made of, for example, oxide, nitride, carbide, boride, sulfide, selenide, or metal. The content thereof is usually not less than 50 wt %, preferably not less than 90 wt %, more preferably not less than 95 wt % based on the inorganic particle. The content of the inorganic particle contained in the semiconductor layer may be determined by a method of cutting a semiconductor multilayer device and then analyzing a cross section of the device using SEM-EDX.

Examples of the oxide include silica, alumina, zirconia, titania, ceria, zinc oxide, tin oxide, and yttrium aluminum garnet (YAG).

Examples of the nitride include silicon nitride and boron nitride.

Examples of the carbide include silicon carbide (SiC), boron carbide, diamond, graphite, and fullerene.

Examples of the boride include zirconium boride (ZrB₂) and chromium boride (CrB₂).

Examples of the sulfide include zinc sulfide, cadmium sulfide, calcium sulfide, and strontium sulfide.

Examples of the selenide include zinc selenide and cadmium selenide.

With regard to the oxide, nitride, carbide, boride, sulfide, and selenide, each element may be partly substituted with other element. Examples of such substance in which each element may be partly substituted with other element include a fluorescent substance made of silicate or aluminate containing cerium or europium as an activator.

Examples of the metal include silicon (Si), nickel (Ni), tungsten (W), tantalum (Ta), chromium (Cr), titanium (Ti), magnesium (Mg), calcium (Ca), aluminum (Al), gold (Au), silver (Ag), and zinc (Zn).

The inorganic particle may be used alone or in combination. Examples of the combination include an inorganic particle containing a nitride particulate and an oxide on the nitride particulate.

Among them, the inorganic particle are preferably made of the oxide, more preferably made of silica.

The inorganic particle may preferably contain a mask material for growth of semiconductor layer. The mask material is more preferably present on the surfaces of the inorganic particle. When the mask material is present on the surfaces of the inorganic particle, the mask material cover area on the surfaces of the inorganic particle is preferably not less than 30%, more preferably not less than 50%. Examples of material of which the mask is made include silica, zirconia, titania, silicon nitride, boron nitride, tungsten (W), molybdenum (Mo), chromium (Cr), cobalt (Co), silicon (Si), aluminum (Al), zirconium (Zr), tantalum (Ta), titanium (Ti), niobium (Nb), nickel (Ni), platinum (Pt), vanadium (V), hafnium (Hf), and palladium (Pd), preferably silica. These materials may be used alone or in combination. The composition of the mask material contained in the inorganic particle may be measured by a method of cutting a semiconductor multilayer device and then analyzing a cross section of the inorganic particles using SEM-EDX.

The inorganic particle may be in the form of sphere (for example, cross section: circular, elliptic), plate (for example, aspect ratio L/T of length L to thickness T: 1.5-100), needle (for example, ratio L/W of length L to width W: 1.5 to 100), or may have no regular shape (the particles have various shapes and are, therefore, not uniform in shape as a whole); preferably may be in the form of sphere. The inorganic particle has an average particle diameter of usually not less than 5 nm, preferably not less than 10 nm, more preferably not less than 0.1 μm, and usually not more than 50 μm, preferably not more than 10 μm, more preferably not more than 1 μm. The use of the inorganic particle with the above average particle diameter makes it possible to form a semiconductor multilayer substrate to provide a high brightness light-emitting device. The form and average particle diameter of the inorganic particle may be measured by a method of cutting the semiconductor multilayer device and then observing a cross section of the particles using electron microscope.

Furthermore, the inorganic particle satisfies that the ratio of d/λ is usually not less than 0.01, preferably not less than 0.02, more preferably not less than 0.2, and usually not more than 100, preferably not more than 30, more preferably not more than 3.0, wherein d represents an average particle diameter (nm) of the inorganic particles and λ represents the emission wavelength (nm) of the light-emitting device including the semiconductor multilayer substrate.

In case of a semiconductor layer made of nitride, for example, when a semiconductor multilayer substrate comprises substrate, buffer layer (GaN, AlN or the like), n-type conductive layer (n-type contact layer or n-type clad layer such as n-GaN, n-AlGaN), light-emitting layer (InGaN, GaN or the like), and p-type conductive layer (p-type contact layer or p-type clad layer such as p-GaN, p-AlGaN) in that order as described in JP-A Nos. 6-260682, 7-15041, 9-64419, and 9-36430, the inorganic particle may be in or on any of the above layers and are preferably on the substrate.

[Substrate]

The substrate is made of, for example, sapphire, SiC, Si, MgAl₂O₄, LiTaO₃, ZrB₂, CrB₂, gallium nitride, or composite obtained by growing a nitride semiconductor on any one of those substances.

The composite may includes a substrate and a low-temperature buffer layer on the substrate. The low-temperature buffer layer is represented by, for example, the formula AlₐGa₁₋ₐN, wherein a is usually not less than 0 and not more than 1, preferably not more than 0.5.

The composite may further include an InGaAlN layer on the low-temperature buffer layer.

In the semiconductor multilayer substrate including the substrate made of sapphire, SiC, Si, MgAl₂O₄, LiTaO₃, ZrB₂, CrB₂, or gallium nitride, since the inorganic particle is placed on the substrate, the junction area between the substrate and the semiconductor layer is small, and therefore the substrate is easily separated from the semiconductor layer as compared with a semiconductor multilayer substrate in which no inorganic particle is placed. The separation is carried out by using, for example, a laser or an ultrasonic wave. When separating the substrate therefrom, an electrically conductive substrate or a high thermal conductivity substrate may be adhered to the semiconductor layer before the separation. In addition, in order to make the semiconductor multilayer substrate function as a light-emitting device, the substrate may be used after the substrate is cut to the proper size.

[Light-Emitting Device]

A light-emitting device according to the present invention includes the semiconductor multilayer substrate described above and an electrode. The electrode is used to supply current to the light-emitting layer and is made of metal such as Au, Pt, Pd; IT; or the like.

In a light-emitting device in which a semiconductor layer is made of metal nitride, the light-emitting device includes layers for the operation of the nitride semiconductor light-emitting device such as n-type conductive layer (n-type contact layer, n-type clad layer, or the like), light-emitting layer, and p-type conductive layer (p-type contact layer, p-type clad layer, or the like). These layers are made of, for example, InₓGa_{y}AlₓN (0≦x≦1, 0≦y≦1, 0≦z≦1, and x+y+z=1). The light-emitting device may further include single layer, multilayer (thick-film layer, superlattice thin-film layer, or the like), or buffer layer in view point of improving crystal quality of the layers for the operation of the nitride semiconductor light-emitting device. The light-emitting device including the metal nitride semiconductor layer may be produced by a method described in Appl. Phys. Lett., Vol. 60, p. 1403, 1996.

In a light-emitting device in which the semiconductor layer is made of high-molecular weight organic compound, the semiconductor layer is used as either an electron transporting layer or a hole transporting layer. The light-emitting device includes semiconductor multilayer substrate, electrodes, and light-emitting layer, and usually includes substrate, anode, hole transporting layer, light-emitting layer, electron transporting layer, and cathode in that order and electrodes.

The substrate is usually made of glass. The anode is made of, for example, ITO. The hole transporting layer is made of polyvinyl carbazole, polyvinyl carbazole derivative, polysilane, polysilane derivative, polysiloxane derivative in which aromatic amine groups attach to its side chains or main chain, polyaniline, polyaniline derivative, polythiophene, or polythiophene derivative. The light-emitting layer is made of, for example, poly (p-phenylenevinylene), polyfluorene (Jpn. J. Appl. Phys., Vol. 30, L1941, 1999), polyparaphenylene derivative (Adv. Mater., Vol. 4, p. 36, 1992), or triplet light-emitting complex such as Ir (ppy)₃, containing iridium as a base metal (Appl. Phys. Lett., Vol. 75, p. 4, 1999). The electron transporting layer is made of oxadiazole derivative, anthraquinodimetane, anthraquinodimetane derivative, benzoquinone, benzoquinone derivative, or the like. The cathode is preferably made of material with small work functions. Examples of the material include lithium, sodium, potassium, rubidium, cesium, beryllium, magnesium, calcium, strontium, barium, and aluminum. The electrode is made of material which supplies current to the light-emitting layer. The light-emitting device in which the semiconductor layer is made of the high-molecular weight organic compound may be produced by, for example, a method described in Nature Vol. 347, p. 539, 1990.

[Method for Producing Semiconductor Multilayer Substrate]

A method for producing a semiconductor multilayer substrate according to the present invention includes step (a) of placing a particle made of substance other than metal nitrides on a substrate.

The substrate is made of sapphire, SiC, Si, MgAl₂O₄, LiTaO₃, ZrB₂, CrB₂, or gallium nitride or composite obtained by growing a nitride semiconductor on any one of those substances.

The composite may be prepared by, for example, growing a low-temperature buffer layer on the substrate. The low-temperature buffer layer may be grown at temperature of 400° C. to 700° C. When growing the low-temperature buffer layer, the buffer layer may be grown in the form of one or more layers.

Furthermore, the composite may be prepared by growing an InGaAlN layer on the low-temperature buffer layer.

The inorganic particle is made of, for example, oxide, nitride, carbide, boride, sulfide, selenide, or metal. The content thereof is usually not less than 50 wt %, preferably not less than 90 wt %, more preferably not less than 95 wt % based on the inorganic particle. The content of the inorganic particle may be determined by chemical analysis, emission spectroscopy, or the like.

Examples of the oxide include silica, alumina, zirconia, titania, ceria, zinc oxide, tin oxide, and yttrium aluminum garnet (YAG).

Examples of the nitride include silicon nitride and boron nitride.

Examples of the carbide include silicon carbide (SiC), boron carbide, diamond, graphite, and fullerenes.

Examples of the boride include zirconium boride (ZrB₂) and chromium boride (CrB₂).

Examples of the sulfide include zinc sulfide, cadmium sulfide, calcium sulfide, and strontium sulfide.

Examples of the selenide include zinc selenide and cadmium selenide.

With regard to the oxide, nitride, carbide, boride, sulfide, and selenide, each element may be partly substituted with other element. Examples of such substance in which each element may be partly substituted with other element include a fluorescent substance made of silicate or aluminate containing cerium or europium as an activator.

Examples of the metal include silicon (Si), nickel (Ni), tungsten (W), tantalum (Ta), chromium (Cr), titanium (Ti), magnesium (Mg), calcium (Ca), aluminum (Al), gold (Au), silver (Ag), and zinc (Zn).

The inorganic particle may be made of substance which can be converted to the above-described oxide, nitride, carbide, boride, sulfide, selenide, or metal by heat treatment. Examples of the substance include silicone. Silicone is a polymer having a structure in which an inorganic bond of Si—O—Si is formed as a backbone and organic substituents attach to the Si portions. The silicone is converted to silica when heat treated at about 500° C.

The particle may be used alone or in combination. Examples of the combination include an inorganic particle containing a nitride particulate and an oxide on the nitride particulate.

Among them, the inorganic particle are preferably made of the oxide, more preferably made of silica.

The inorganic particle may preferably contain a mask material for growth of semiconductor layer. The mask material is more preferably present on the surfaces of the inorganic particle. When the mask material is present on the surfaces of the inorganic particle, the mask material cover area on the surfaces of the inorganic particle is preferably not less than 30%, more preferably not less than 50%. Examples of material of which the mask is made include silica, zirconia, titania, silicon nitride, boron nitride, tungsten (W), molybdenum (Mo), chromium (Cr), cobalt (Co), silicon (Si), aluminum (Al), zirconium (Zr), tantalum (Ta), titanium (Ti), niobium (Nb), nickel (Ni), platinum (Pt), vanadium (V), hafnium (Hf), and palladium (Pd), preferably silica. These materials may be used alone or in combination. The inorganic particle which contains a mask material on its surface may be prepared by, for example, a method of forming a mask material on the particle surface by deposition or sputtering, or a method of hydrolyzing a compound on the particle surface.

The inorganic particle may be in the form of sphere (for example, cross section: circular, elliptic), plate (for example, aspect ratio L/T of length L to thickness T: 1.5-100), needle (for example, ratio L/W of length L to width W: 1.5 to 100), or no regular shape (the particles have various shapes and are, therefore, not uniform in shape as a whole); preferably in the form of sphere. Therefore it is more preferable to use spherical silica as the inorganic particle. As the spherical silica, the use of colloidal silica is recommended in terms of availability of silica which is monodisperse and has a relatively uniform particle diameter. Colloidal silica is a suspension in which silica particle is dispersed into a solvent such as water in colloidal form and such a suspension is prepared through the ion exchange of sodium silicate or the hydrolysis of an organosilicon compound such as tetraethyl orthosilicate (TEOS) The inorganic particle has an average particle diameter of usually not less than 5 nm, preferably not less than 10 nm, more preferably not less than 0.1 μm, and usually not more than 50 μm, preferably not more than 10 μm, more preferably not more than 1 μm. The use of the inorganic particle with the above average particle diameter makes it possible to form a semiconductor multilayer substrate to provide a high brightness light-emitting device.

Furthermore, the inorganic particle satisfies that the ratio of d/λ is usually not less than 0.01, preferably not less than 0.02, more preferably not less than 0.2, and usually not more than 100, preferably not more than 30, more preferably not more than 3.0, wherein d represents an average particle diameter (nm) of the inorganic particles and λ represents the emission wavelength (nm) of the light-emitting device including the semiconductor multilayer substrate.

The average particle diameter refers to a volumetric average particle diameter measured by centrifugal sedimentation. The average particle diameter may be measured by a method other than centrifugal sedimentation, for example, dynamic light-scattering, Coulter counter, laser diffraction, or electron microscopy; in that case, it is required only to calibrate the average particle diameter to the volumetric average particle diameter measured by centrifugal sedimentation. For example, the average particle diameter of the standard particle is determined by both centrifugal sedimentation and another method, and then the correlation coefficient of these average particle diameters is calculated. It is preferable that the correlation coefficient is determined by calculating the correlation coefficient of the average particle diameter of the standard particles with different particle diameters to the volumetric average particle diameter determined by centrifugal sedimentation and then drawing a calibration curve. The use of the calibration curve makes it possible to determine the volumetric average particle diameter from the average particle diameter determined by the method other than centrifugal sedimentation.

The placement of the inorganic particle may be carried out by, for example, a method of dipping the substrate in a slurry containing the inorganic particle and a solvent, or a method of applying or spraying the slurry onto the substrate and then drying the slurry. Examples of the solvent include water, methanol, ethanol, isopropanol, n-butanol, ethylene glycol, dimethylacetamide, methyl ethyl ketone, and methyl isobutyl ketone; preferably water. The application is preferably carried out by spin coating. According of this method, the inorganic particle is placed in uniform density. The drying may be carried out using a spinner.

The coverage factor of the inorganic particles to the substrate may be determined as follows:
coverage factor (%)=((d/2)²×π·P·100)/S
wherein d is the average particle diameter of the inorganic particles and P is the number of the particles in the scanning electron microscopic view (area S) of top-looking of the substrate on which the particles are placed.

The coverage factor of the inorganic particles to the substrate is usually not less than 0.1%, preferably not less than 5%, more preferably not less than 30%, and usually not more than 90%, preferably not more than 80%.

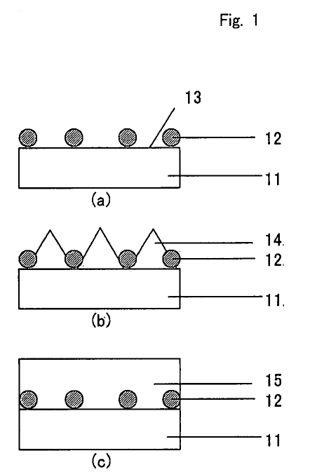

The inorganic particles may be placed in at least two layers on the substrate. It is preferable that the inorganic particles are placed in one layer, for example, at least 90% of the inorganic particles are placed in one layer. When the inorganic particles are placed in one layer, the semiconductor layer grows epitaxially, thereby flattening proceeds. FIG. 1(a) illustrates a cross-sectional view of a structure in which the inorganic particles are placed on the substrate.

The method according to the invention includes further step (b) of growing a semiconductor layer on the resultant obtained in the step (a).

Examples of material for the semiconductor layer include metal nitrides, preferably group III-V nitrides represented by the formula InₓGa_{y}Al_{z}N (0≦x≦1, 0≦y≦1, 0z≦1, and x+y+z=1). The semiconductor layer may be grown in one layer, or more than one layer.

Furthermore, any one of the semiconductor layer in which a facet structure is formed and the semiconductor layer in which a facet structure is not formed may be used; when the coverage factor of the inorganic particle is high, it is preferable to use the semiconductor layer in which the facet structure is formed. The semiconductor layer in which the facet structure is formed is easily flattened.

In case that the semiconductor layer is grown while forming the facet structure, the preferred composition of the group III-V nitride semiconductor layer depends on the particle diameter and placement state of the inorganic particle; when the coverage factor of the inorganic particle is high, it is preferable that Al content is high. However, in case that a GaN layer or an AlGaN layer with Al content lower than that in the facet structure is used as a flattening layer, when Al content in the group III-V nitride semiconductor layer becomes too high, lattice mismatching between the flattening layer and the facet structure increases, which may cause crack and dislocation in the substrate.

Al content in the facet structure may be adjusted according to the particle diameter and placement state of the inorganic particle to grow a crystal which is not cracked and is excellent in crystallinity. For example, when the coverage factor of the inorganic particle is not less than 50%, it is preferable to grow a facet structure represented by the formula Al_{d}Ga_{1-d}N [0≦d≦1] and it is more preferable to grow a facet structure represented by the formula Al_{d}Ga_{1-d}N [0.01≦d≦0.5] (AlN mole fraction is not less than 1.0%, not more than 50%).

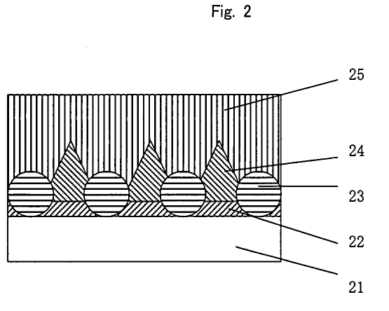

A growth temperature of facet structure is usually not less than 700° C., preferably not less than 750° C., and usually not more than 1000° C., preferably not more than 950° C. When a low-temperature buffer layer is grown, the growth temperature of facet structure is preferably between a growth temperature for the low-temperature buffer layer and a growth temperature for the flattening layer. The facet forming layer may be grown in the form of one layer or more than one layer. As an embodiment of a semiconductor multilayer substrate including the low-temperature buffer layer, FIG. 2 shows a semiconductor multilayer substrate in which substrate 21, low-temperature buffer layer 22, facet structure 24, and semiconductor layer 25 are included and inorganic particle 23 placed on the substrate 21.

When the low-temperature buffer layer is grown, the crystal nucleus of the semiconductor layer (for example, the nitride semiconductor layer) tends to be easily grown, and therefore the semiconductor layer with high crystallinity (for example, semiconductor layer having the full width at half maximum FWHM of the diffraction peak of (302) plane calculated from X-ray diffraction rocking curb below 650 arcsec, preferably below 550 arcsec) grows. The composition of the low-temperature buffer layer is represented by, for example, the formula AlₐGa₁₋ₐN [a is usually not less than 0, and not more than 1, preferably not more than 0.5].

X-ray diffraction rocking curve measurement is used to evaluate crystalline orientation of layer. In this measurement, the incidence angle and detection angle of X ray are set such that a specified lattice face of a sample satisfies diffraction conditions, the angle to the sample is changed in the above state to measure the dependence of the intensity of diffracted light on the angle, and variations in crystal orientation in the plane are evaluated from the degree of the spread of the light. The degree of variations in crystal orientation is usually represented by the full width at half maximum of the peak of X-ray diffraction rocking curve. In a semiconductor which is grown on the C plane of a sapphire substrate, a hexagonal column crystal tends to be easily grown and the tilt of the crystal may be evaluated by the diffraction measurement of lattice faces parallel to the C plane such as (002) and (004) planes. In addition, twist of crystal axis in the C plane may be evaluated by the diffraction measurement of lattice faces which incline from the C plane. For example twist of crystal axis in the C plane may be evaluated based on diffraction peaks of (102) plane, (302) plane, and so on.

The growth may be carried out by an epitaxial growth method such as MOVPE, molecular beam epitaxy (MBE), hydride vapor phase epitaxy (HVPE).

When the group III-V nitride semiconductor layer is grown by MOVPE, the growth may be carried out by a method in which the group III and V materials set forth below are supplied into a reactor using a carrier gas.

Examples of the group III material include: trialkyl gallium expressed by the formula R₁R₂R₃Ga [R₁, R₂, and R₃ are lower alkyl groups] such as trimethyl gallium [TMG, (CH₃)₃Ga] and triethyl gallium [TEG, (C₂H₅)₃Ga]; trialkyl aluminum expressed by the formula R₁R₂R₃Al [R₁, R₂, and R₃ are lower alkyl groups] such as trimethyl aluminum [TMA, (CH₃)₃Al], triethyl aluminum [TEA, (C₂H₅)₃Al], and triisobutyl aluminum [(i-C₄H₉)₃Al]; trimethylaminealane [(CH₃)₃N:AlH₃]; trialkyl indium expressed by the formula R₁R₂R₃In [R₁, R₂, and R₃ are lower alkyl groups] such as trimethyl indium [TMI, (CH₃)₃In] and triethyl indium [(C₂H₅)₃In]; compounds given by substituting one or two alkyl groups of trialkyl indium with one or two atoms of halogen such as diethyl indium chloride [(C₂H₅)₃InCl]; and indium halide expressed by the formula InX [X is an atom of halogen] such as indium chloride [InCl]. These materials may be used alone or in combination.

Among the group III materials, it is preferable to use TMG as a source of gallium, TMA as a source of aluminum, and TMI as a source of indium.

Examples of the group V material include ammonia, hydrazine, methylhydrazine, 1,1-dimethylhydrazine, 1,2-dimethylhydrazine, t-butylamine, and ethylenediamine. These materials may be used alone or in combination. Among the group V materials, it is preferable to use ammonia or hydrazine and it is more preferable to use ammonia.

Examples of an atmospheric gas used at the time of the growth and the carrier gas for the materials include nitrogen, hydrogen, argon, and helium; preference is given to hydrogen and helium. These gases may be used alone or in combination.

The reactor contains, for example, reactor, feed line which supplies the materials from a storage container to the reactor, and a susceptor. The susceptor is an apparatus for use in heating the substrate and is placed in the reactor, and moreover, the susceptor is usually rotated by power to grow the semiconductor layer evenly. The susceptor has a heating unit such as an infrared lamp inside. The materials supplied through the feed line to the reactor are pyrolyzed on the substrate by the heating unit to grow the semiconductor layer on the substrate through vapor deposition. The unreacted part of the materials supplied to the reactor is usually exhausted from the reactor into a waste gas treatment apparatus through an exhaust line.

When the group III-V nitride semiconductor layer is grown by HVPE, the growth is carried out by a method in which the group III and V materials set forth below are charged into the reactor using carrier gas.

Examples of the group III material include gallium chloride gas generated by reacting gallium and hydrogen chloride gas at a high temperature and indium chloride gas generated by reacting indium and hydrogen chloride gas at a high temperature.

Examples of the group V material include ammonia.

Examples of the carrier gas include nitrogen, hydrogen, argon, and helium, preferably hydrogen and helium. These gases may be used alone or in combination.

When the group III-V nitride semiconductor layer is grown by MBE, the growth of the semiconductor layer may be carried out by a method in which the group III and V materials set forth below are charged into the reactor by using carrier gas.

Examples of the group III material include metals such as gallium, aluminum, and indium.

Examples of the group V material include gases such as nitrogen and ammonia.

Examples of the carrier gas include nitrogen, hydrogen, argon, and helium, preferably hydrogen and helium. These gases may be used alone or in combination.

In the method according to the invention, steps (a) and (b) may be repeated or steps (a), (b), and (c) may be repeated. A repetition of the steps makes it possible to produce a semiconductor multilayer substrate which is used as a high-brightness light-emitting device.

In step (b), the semiconductor layer usually starts to grow on a region where no inorganic particle is present as a growth region (see reference numeral 13 of FIG. 1(a)), following which the facet structure is formed (see FIG. 1(b)).

Preferably, the method according to the invention further includes step (c) of growing a semiconductor layer after step (b) and flattering the surface of the semiconductor layer.

At step (c), the semiconductor layer is grown while forming the facet structure by, for example, promoting the lateral growth of the semiconductor layer, thereby the surface of the semiconductor layer is flattened with the facet structure of the resulting substrate embedded therein (see FIG. 1(c)). Through such growth of the semiconductor layer, dislocations having reached the facets are bent sideward and the inorganic particles are embedded in the semiconductor layer. As a result, crystal defects in the semiconductor layer reduce.

The semiconductor multilayer substrate with the semiconductor layer made of high-molecular weight compound may likewise be produced by the method including the steps of disposing an inorganic particle on the substrate and forming the semiconductor layer on the particle. The semiconductor multilayer substrate, For example, may be produced by a method in which an anode (for example, ITO layer having a thickness of 100 to 200 nm) is formed on a substrate (for example, glass substrate) by sputtering, solution of poly(ethylenedioxythiophene)/polystyrene sulfonic acid (Tradename “Baytron” from Bayer Co.) containing inorganic particles is applied onto the anode by coating, the solution is dried to form a hole transporting layer (for example, 50 nm thick), chloroform solution of a high-molecular weight compound light-emitting substance is applied onto the layer by spin coating, the solution is dried at 80° C. under reduced pressure to form a light-emitting layer (for example, 70 nm thick), and then

a cathode buffer layer (for example, lithium fluoride layer with a thickness of 0.4 nm), cathode (for example, calcium layer with a thickness of 25 nm), and aluminum layer (for example, thickness: 40 nm) are formed in that order by vapor deposition.

### EXAMPLES

The following examples further illustrate the present invention; however, the examples are not intended to limit the scope of the invention.

### Example 1

### Placement of Inorganic Particle

A sapphire crystal with a mirror-polished C plane was used as a substrate. Colloidal silica (manufactured by Fuso Chemical Co., Ltd., Trade name PL-20, average particle diameter: 370 nm, particle concentration: 24 wt %) was used as inorganic particles. The substrate was placed on a spinner and a 10 wt % solution of the colloidal silica was applied onto the substrate by spin coating. When observed with a scanning electron microscope, the coverage factor of the colloidal silica particles to the surface of the substrate was 39%.

[Growth of Semiconductor Layer]

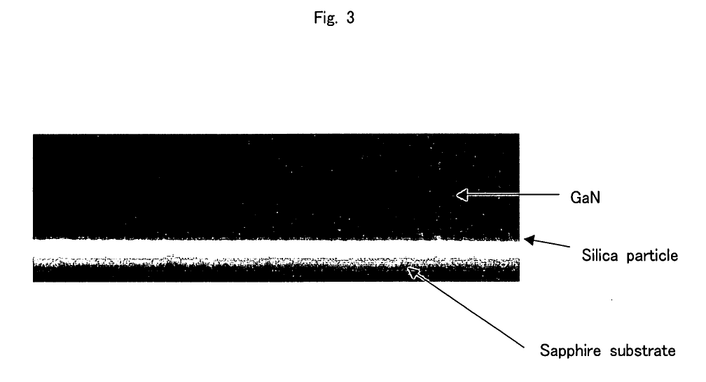

A nitride semiconductor layer was epitaxially grown on the substance and embedded colloidal silica particles. The epitaxial growth was carried out by atmospheric pressure MOVPE. A carrier gas (hydrogen), ammonia, and TMG were fed into a susceptor and heated at 485° C. at 1 atmospheric pressure to grow a GaN low-temperature buffer layer having a thickness of about 500 Å. Then a carrier gas, ammonia, TMG were fed into the susceptor and heated at 900° C. to grow an undoped GaN layer to form a facet structure. Thereafter, a carrier gas, ammonia, and TMG are fed into the susceptor and heated at 1040° C. and a quarter atmospheric pressure to grow an undoped GaN layer having a thickness of about 5 μm, to obtain a nitride semiconductor multilayer substrate in which the colloidal silica particles in the form of a layer are contained in the GaN layer. FIG. 3 shows an electron microscope photograph of the cross section of the nitride semiconductor multilayer substrate. And further, when the cross section of the nitride semiconductor multilayer substrate was observed by using a transmission electron microscope, dislocations bent sharply.

The full width at half maximum of the diffraction peak of a (302) plane calculated from X-ray diffraction rocking curve was 494 arcsec and the full width at half maximum of the diffraction peak of a (004) plane was 215 arcsec.

[Production of Light-Emitting Device]

A n-type semiconductor layer, InGaN light-emitting layer (MQW structure), p-type semiconductor layer were grown on the nitride semiconductor multilayer substrate in that order. Etching was carried out to expose the n-type contact layer, an electrode was formed to obtain a device. The device was cut into a device chip (blue LED) with an emission wavelength of 440 nm (d/λ=0.8). The blue LED had a light output of 8.5 mW at a current of 20 mA.

### Example 2

A blue LED (d/λ=1.3) was produced in the same operation as [PLACEMENT OF INORGANIC PARTICLE], [GROWTH OF SEMICONDUCTOR LAYER], and [PRODUCTION OF LIGHT-EMITTING DEVICE] in Example 1 except that 10 wt % diluted liquid of colloidal silica (manufactured by Nippon Shokubai Co., Ltd., trade name: SEAHOSTER KE-W50, average particle diameter: 550 nm, particle concentration: 20 wt %) was used as inorganic particles. The coverage factor of the colloidal silica particles to the surface of the substrate was 36%.

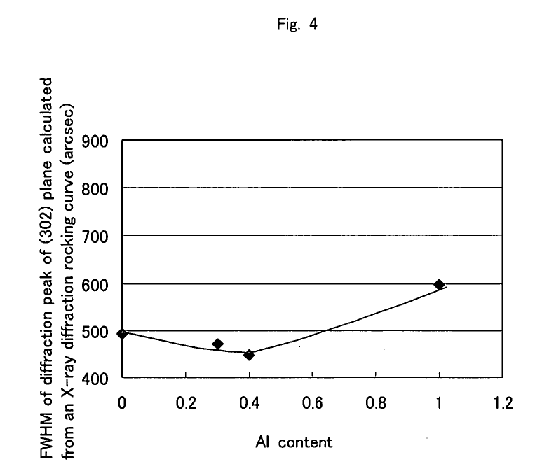

The full width at half maximum of the diffraction peak of (302) plane calculated from X-ray diffraction rocking curve was 493 arcsec and the full width at half maximum of the diffraction peak of (004) plane was 220 arcsec. FIG. 4 shows the relationship between Al content in a low-temperature buffer layer and the full width at half maximum of the diffraction peak of the (302) plane.

The blue LED had a light output of 9.9 mW at a current of 20 mA.

### Example 3

A blue LED (d/λ=0.8) was produced in the same operation as [PLACEMENT OF INORGANIC PARTICLE], [GROWTH OF SEMICONDUCTOR LAYER], and [PRODUCTION OF LIGHT-EMITTING DEVICE] in Example 1 except that a substance obtained by growing a GaN layer on a sapphire crystal with a mirror-polished C plane was used as a substrate. The coverage factor of colloidal silica particles to the surface of the substrate was 32%. The blue LED had a light output of 7.3 mW at a current of 20 mA.

### Example 4

A blue LED was produced in the same operation as [PLACEMENT OF INORGANIC PARTICLE] in Example 1 except that 10 wt % diluted liquid of colloidal silica (manufactured by Nissan Chemical Industries Ltd., Trade name: MP-1040, average particle diameter: 100 nm, particle concentration: 40 wt %) was used as inorganic particles. The coverage factor of the colloidal silica particles to the surface of a substrate was 55%.

[Growth of Semiconductor Layer and Production of Light-Emitting Device]

A blue LED (d/λ=0.2) was produced in the same operation as [GROWTH OF SEMICONDUCTOR LAYER] and [PRODUCTION OF LIGHT-EMITTING DEVICE] in Example 1 except that facet structures were formed at two layers, i.e., facet structures were formed at an undoped AlGaN layer (AlN mole fraction: 1.7%) at 800° C. and at an undoped GaN layer at 900° C. The blue LED had a light output 2.4 times higher than a blue LED containing no silica at a current of 20 mA.

### Example 5

A blue LED (d/λ=0.5) was produced in the same operation as [PLACEMENT OF INORGANIC PARTICLE], [GROWTH OF SEMICONDUCTOR LAYER], and [PRODUCTION OF LIGHT-EMITTING DEVICE] in Example 1 except that 10 wt % diluted liquid of colloidal silica (manufactured by Nissan Chemical Industries Ltd., Trade name: MP-2040, average particle diameter: 200 nm, particle concentration: 40 wt %) was used as inorganic particles. The coverage factor of the colloidal silica particles to the surface of a substrate was 40%. The blue LED had a light output 2.2 times higher than a blue LED containing no silica at a current of 20 mA.

### Example 6

Except that 20 wt % diluted liquid of colloidal silica (manufactured by Nissan Chemical Industries Ltd., Trade name: MP-2040, average particle diameter: 200 nm, particle concentration: 40 wt %) was used as inorganic particles, the same operation as [PLACEMENT OF INORGANIC PARTICLE] in Example 1 was carried out. The coverage factor of the colloidal silica particles to the surface of a substrate was 76%.

A blue LED (d/λ=0.5) was produced in the same operation as [GROWTH OF SEMICONDUCTOR LAYER] and [PRODUCTION OF LIGHT-EMITTING DEVICE] in Example 4

The blue LED had a light output 2.7 times higher than a blue LED containing no silica at a current of 20 mA.

### Example 7

Except that 20 wt % diluted liquid of colloidal silica (manufactured by Nissan Chemical Industries Ltd., Trade name: MP-3040, average particle diameter: 300 nm, particle concentration: 40 wt %) was used as inorganic particles, the same operation as [PLACEMENT OF INORGANIC PARTICLE] in Example 1 was carried out. The coverage factor of the colloidal silica particles to the surface of a substrate was 37%.

A blue LED (d/λ=0.7) was produced in the same operation as [GROWTH OF SEMICONDUCTOR LAYER] and [PRODUCTION OF LIGHT-EMITTING DEVICE] in Example 4

The blue LED had a light output 3.5 times higher than a blue LED containing no silica at a current of 20 mA.

### Example 8

Except that 30 wt % diluted liquid of colloidal silica (manufactured by Nissan Chemical Industries Ltd., Trade name: MP-3040, average particle diameter: 300 nm, particle concentration: 40 wt %) was used as inorganic particles, the same operation as [PLACEMENT OF INORGANIC PARTICLE] in Example 1 was carried out. The coverage factor of the colloidal silica particles to the surface of a substrate was 71%.

A blue LED (d/λ=0.7) was produced in the same operation as [GROWTH OF SEMICONDUCTOR LAYER] and [PRODUCTION OF LIGHT-EMITTING DEVICE] in Example 4

The blue LED had a light output 3.3 times higher than a blue LED containing no silica at a current of 20 mA.

### Example 9

Except that 20 wt % diluted liquid of colloidal silica (manufactured by Nissan Chemical Industries Ltd., Trade name: MP-4540, average particle diameter: 450 nm, particle concentration: 40 wt %) was used as inorganic particles, the same operation as [PLACEMENT OF INORGANIC PARTICLE] in Example 1 was carried out. The coverage factor of the colloidal silica particles to the surface of a substrate was 30%.

A blue LED (d/λ=1.0) was produced in the same operation as [GROWTH OF SEMICONDUCTOR LAYER] and [PRODUCTION OF LIGHT-EMITTING DEVICE] in Example 4

The blue LED had a light output 3.0 times higher than a blue LED containing no silica at a current of 20 mA.

### Example 10

Except that 30 wt % diluted liquid of colloidal silica (manufactured by Nissan Chemical Industries Ltd., Trade name: MP-4540, average particle diameter: 450 nm, particle concentration: 40 wt %) was used as inorganic particles, the same operation as [PLACEMENT OF INORGANIC PARTICLE] in Example 1 was carried out. The coverage factor of the colloidal silica particles to the surface of a substrate was 48%.

A blue LED (d/λ=1.0) was produced in the same operation as [GROWTH OF SEMICONDUCTOR LAYER] and [PRODUCTION OF LIGHT-EMITTING DEVICE] in Example 4

The blue LED had a light output 4.5 times higher than a blue LED containing no silica at a current of 20 mA.

### Example 11

Except that colloidal silica (manufactured by Nissan Chemical Industries Ltd., Trade name: MP-4540, average particle diameter: 450 nm, particle concentration: 40 wt %) was used as inorganic particles, the same operation as [PLACEMENT OF INORGANIC PARTICLE] in Example 1 was carried out. The coverage factor of the colloidal silica particles to the surface of a substrate was 48%.

A blue LED (d/λ=1.0) was produced in the same operation as [GROWTH OF SEMICONDUCTOR LAYER] and [PRODUCTION OF LIGHT-EMITTING DEVICE] in Example 4

The blue LED had a light output 3.0 times higher than a blue LED containing no silica at a current of 20 mA.

### Example 12

Except that 10 wt % diluted liquid of colloidal silica (manufactured by Nippon Shokubai Co., Ltd., trade name: SEAHOSTER KE-W50, average particle diameter: 550 nm, particle concentration: 20 wt %) was used as inorganic particles, the same operation as [PLACEMENT OF INORGANIC PARTICLE] in Example 1 was carried out.

A blue LED (d/λ=1.3) was produced in the same operation as [GROWTH OF SEMICONDUCTOR LAYER] and [PRODUCTION OF LIGHT-EMITTING DEVICE] in Example 4

The blue LED had a light output 2.4 times higher than a blue LED containing no silica at a current of 20 mA.

### Example 13

Except that colloidal silica (manufactured by Nippon Shokubai Co., Ltd., trade name: SEAHOSTER KE-W50, average particle diameter: 550 nm, particle concentration: 20 wt %) was used as inorganic particles, the same operation as [PLACEMENT OF INORGANIC PARTICLE] in Example 1 was carried out. The coverage factor of the colloidal silica particles to the surface of a substrate was 60%.

A blue LED (d/λ=1.3) was produced in the same operation as [GROWTH OF SEMICONDUCTOR LAYER] and [PRODUCTION OF LIGHT-EMITTING DEVICE] in Example 4

The blue LED had a light output 2.9 times higher than a blue LED containing no silica at a current of 20 mA.

### Example 14

Except that ethanol dispersion containing 8 wt % silica (manufactured by Ube-Nitto Kasei Co., Ltd., Trade name: Hipresica UF, average particle diameter: 1.0 μm) was used as inorganic particles, the same operation as [PLACEMENT OF INORGANIC PARTICLE] in Example 1 was carried out. The coverage factor of the silica particles to the surface of a substrate was 56%.

A blue LED (d/λ=2.3) was produced in the same operation as [GROWTH OF SEMICONDUCTOR LAYER] and [PRODUCTION OF LIGHT-EMITTING DEVICE] in Example 4

The blue LED had a light output 2.2 times higher than a blue LED containing no silica at a current of 20 mA.

### Comparative Example 1

A blue LED was produced in the same operation as [PLACEMENT OF INORGANIC PARTICLE], [GROWTH OF SEMICONDUCTOR LAYER], and [PRODUCTION OF LIGHT-EMITTING DEVICE] in Example 1 except that no inorganic particle was used.

The blue LED had a light output of 5.0 mW at a current of 20 mA.

### Comparative example 2

A SiO₂ film having a thickness of 100 nm was formed on a substrate by sputtering, following which a striped pattern having opening portions having a width of 5 μm and pattern portions having a width of 5 μm in a <1-100> direction was formed by conventional photolithography. Using the obtained substrate, a nitride semiconductor multilayer substrate was formed in the same operation as Example 1, and then a nitride semiconductor light-emitting device was produced. The nitride semiconductor light-emitting device had a light output of 4.5 mW at a current of 20 mA.

Test 1

Except that 10 wt % diluted liquid of colloidal silica (manufactured by Nippon Shokubai Co., Ltd., trade name: SEAHOSTER KE-W50, average particle diameter: 550 nm, particle concentration: 20 wt %) was used as inorganic particles, and that a low-temperature buffer layer (to be grown at susceptor temperature of 485° C.) was not grown, the same operation as [PLACEMENT OF INORGANIC PARTICLE] and [GROWTH OF SEMICONDUCTOR LAYER] in Example 1 was carried out.

The obtained semiconductor multilayer substrate had considerable asperities on its surface, and therefore a mirror surface was not formed.

Test 2

Except that 10 wt % diluted liquid of colloidal silica (manufactured by Nippon Shokubai Co., Ltd., trade name: SEAHOSTER KE-W50, average particle diameter: 550 nm, particle concentration: 20 wt %) was used as inorganic particles, and that an undoped GaN layer (to be grown at susceptor temperature of 900° C.) in which facet structures are to be formed was not grown, the same operation as [PLACEMENT OF INORGANIC PARTICLE] and [GROWTH OF SEMICONDUCTOR LAYER] in Example 1 was carried out.

The obtained semiconductor multilayer substrate had considerable asperities on its surface, and therefore a mirror surface was not formed.

Test 3

Except that 10 wt % diluted liquid of colloidal silica (manufactured by Nippon Shokubai Co., Ltd., trade name: SEAHOSTER KE-W50, average particle diameter: 550 nm, particle concentration: 20 wt %) was used as inorganic particles, and that a low-temperature buffer layer grown at susceptor temperature of 485° C. was represented by Al_{0.3}Ga_{0.7}N, the same operation as [PLACEMENT OF INORGANIC PARTICLE] and [GROWTH OF SEMICONDUCTOR LAYER] in Example 1 was carried out to obtain a semiconductor multilayer substrate. In the semiconductor multilayer substrate, the full width at half maximum (FWHM) of the diffraction peak of (004) plane calculated from an X-ray diffraction rocking curve was 194 arcsec and that of (302) plane was 470 arcsec. FIG. 4 shows the relationship between Al content in the low-temperature buffer layer and the full width at half maximum of diffraction peak of (302) plane.

Test 4

Except that a low-temperature buffer layer grown at susceptor temperature of 485° C. was represented by Al_{0.4}Ga_{0.6}N, the same operation as Test 3 was carried out to obtain a semiconductor multilayer substrate. In the semiconductor multilayer substrate, the full width at half maximum (FWHM) of the diffraction peak of (004) plane calculated from an X-ray diffraction rocking curve was 199 arcsec and that of (302) plane was 447 arcsec. The result was shown in FIG. 4.

Test 5

Except that a low-temperature buffer layer grown at susceptor temperature of 485° C. was represented by AlN, the same operation as Test 3 was carried out to obtain a semiconductor multilayer substrate. In the semiconductor multilayer substrate, the full width at half maximum (FWHM) of the diffraction peak of (004) plane calculated from an X-ray diffraction rocking curve was 283 arcsec and that of (302) plane was 596 arcsec. The result was shown in FIG. 4.

Test 6

Except that a low-temperature buffer layer to be grown at susceptor temperature of 485° C. was not grown, the same operation as Test 3 was carried out to obtain a semiconductor multilayer substrate. The obtained semiconductor multilayer substrate had considerable asperities on its surface, and therefore a mirror surface was not formed.

### INDUSTRIAL APPLICABILITY

The present invention provides the semiconductor multilayer substrate used as a high-brightness semiconductor light-emitting device. The invention provides the method for producing the semiconductor multilayer substrate. Furthermore, the invention provides the light-emitting device including the semiconductor multilayer substrate.

1. A semiconductor multilayer substrate comprising a semiconductor layer containing an inorganic particle made of substance other than metal nitrides.

2. The semiconductor multilayer substrate according to claim 1, wherein the semiconductor layer includes metal nitride, high-molecular weight organic compound, or low-molecular weight organic compound in addition to the inorganic particle.

3. The semiconductor multilayer substrate according to claim 2, wherein the semiconductor layer includes metal nitride in addition to the inorganic particle.

4. The semiconductor multilayer substrate according to claim 1, wherein the inorganic particle is made of at least one selected from the group consisting of oxide, nitride, carbide, boride, sulfide, selenide, and metal.

5. The semiconductor multilayer substrate according to claim 4, wherein the inorganic particle is made of oxide.

6. The semiconductor multilayer substrate according to claim 5, wherein the oxide is at least one selected from the group consisting of silica, alumina, zirconia, titania, ceria, magnesia, zinc oxide, tin oxide, and yttrium aluminum garnet.

7. The semiconductor multilayer substrate according to claim 6, wherein the oxide is silica.

8. The semiconductor multilayer substrate according to claim 1, wherein the inorganic particle contains a mask material for growth of semiconductor layer.

9. The semiconductor multilayer substrate according to claim 8, wherein the inorganic particle contains the mask material on its surface.

10. The semiconductor multilayer substrate according to claim 9, wherein the mask material cover area on the surfaces of the inorganic particle is not less than 30%.

11. The semiconductor multilayer substrate according to claim 8, wherein the mask material is made of at least one selected from the group consisting of silica, zirconia, titania, silicon nitride, boron nitride, W, Mo, Cr, Co, Si, Au, Zr, Ta, Ti, Nb, Pt, V, Hf, and Pd.

12. The semiconductor multilayer substrate according to claim 1, wherein the inorganic particle is in the shape of sphere, plate, needle, or has no regular shape.

13. The semiconductor multilayer substrate according to claim 12, wherein the inorganic particle is in the shape of sphere.

14. The semiconductor multilayer substrate according to claim 1, wherein the inorganic particle has an average particle diameter of 5 nm to 50 μm.

15. The semiconductor multilayer substrate according to claim 1, which further comprising a substrate.

16. A method for producing a semiconductor multilayer substrate, comprising the steps (a) and (b) of:
(a) placing an inorganic particle made of substance other than metal nitrides on a substrate and
(b) growing a semiconductor layer.

17. The method for producing a semiconductor multilayer substrate according to claim 16, wherein step (b) is followed by step (c) growing a semiconductor layer and flattening the surface of the layer.

18. A method for producing a semiconductor multilayer substrate, comprising the steps (a1), (a2) and (b) of:
(a1) placing an inorganic particle made of substance other than metal nitrides on a substrate,
(a2) growing a low-temperature buffer layer; and
(b) growing a semiconductor layer.

19. The method for producing a semiconductor multilayer substrate according to claim 18, wherein step (b) is followed by step (c) of growing a semiconductor layer and flattening the surface of the layer.

20. The method for producing a semiconductor multilayer substrate according to claim 19, wherein a growth temperature in the step (b) is between a growth temperature in the step (a2) and a growth temperature in the step (c).

21. The method for producing a semiconductor multilayer substrate according to claim 16, wherein
the semiconductor layer satisfies the full width at half maximum (FWHM) of the diffraction peak of (302) plane calculated from an X-ray diffraction rocking curve is not more than 650 arcsec.

22. The method for producing a semiconductor multilayer substrate according to claim 16, wherein the semiconductor layer contains a metal nitride.

23. The method for producing a semiconductor multilayer substrate according to claim 16, wherein the semiconductor layer is grown by any one selected from the group consisting of metal organic chemical vapor deposition, molecular-beam epitaxy, and hydride vapor deposition.

24. The method for producing a semiconductor multilayer substrate according to claim 16, wherein the semiconductor layer has a facet structure and is represented by the formula InₓGa_{y}Al_{z}N (0?x?1, 0?y?1, 0?z?1, and x+y+Z=1).

25. The method for producing a semiconductor multilayer substrate according to claim 24, wherein the semiconductor layer has a facet structure and is represented by the Al_{d}Ga_{1-d}N (0≦d≦1).

26. The method for producing a semiconductor multilayer substrate according to claim 16, wherein the inorganic particle is placed so as to cover 0.1% to 90% of the growth surface of the substrate.

27. The method for producing a semiconductor multilayer substrate according to claim 16, wherein the placement is carried out by spin coating.

28. A light-emitting device comprising the semiconductor multilayer substrate according to claim 1.

29. The light-emitting device according to claim 28, which further comprising an electrode.

30. The light-emitting device according to claim 28, wherein the ratio of d/λ where d represents an average particle diameter of the inorganic particle and λ represents an emission wavelength of the light-emitting device is not less than 0.2, not more than 3.0.

31. A use of a semiconductor multilayer substrate comprising a semiconductor layer containing an inorganic particle made of substance other than metal nitrides as a light-emitting device.

32. A semiconductor multilayer substrate obtained by the method according to the claim 16.
